(19) United States
(12) Patent Application Publication
(10) Pub. No.: US 2020/0118824 A1
(43) Pub. Date: Apr. 16, 2020

(54) FILM FORMING METHOD AND SUBSTRATE PROCESSING SYSTEM

(71) Applicant: TOKYO ELECTRON LIMITED, Tokyo (JP)

(72) Inventor: Mitsuhiro OKADA, Nirasaki City (JP)

(21) Appl. No.: 16/591,750

(22) Filed: Oct. 3, 2019

(30) Foreign Application Priority Data
Oct. 12, 2018 (JP) 2018193768

(51) Int. Cl. H01L 21/285; H01L 21/768; H01L 21/3213; H01L 21/02; H01L 21/67

(52) U.S. Cl. CPC H01L 21/28562; H01L 21/76879; H01L 21/67184; H01L 21/0228; H01L 21/32135

(57) ABSTRACT

A film forming method of embedding a metal film in a recess, which is formed in a substrate and has an insulating film formed on a surface of the recess, includes: conformally forming a base film in the recess; etching the base film such that a surface of the insulating film formed on an upper portion of an inner wall of the recess is exposed and the base film remains on a bottom portion in the recess; and selectively growing the metal film on the base film remaining on the bottom portion in the recess.

### CROSS-REFERENCE TO RELATED APPLICATION

This application is based upon and claims the benefit of priority from Japanese Patent Application No. 2018-193768, filed on Oct. 12, 2018, the entire contents of which are incorporated herein by reference.

### TECHNICAL FIELD

The present disclosure relates to a film forming method and a substrate processing system.

### BACKGROUND

A film forming method capable of embedding a tungsten film in a recess having a high aspect ratio, such as a trench or a hole, without generating a void inside the recess is known (see, e.g., Patent Document 1).

### PRIOR ART DOCUMENTS

### Patent Documents

Patent Document 1: Japanese laid-open publication No. 2015-190020

### SUMMARY

An aspect of the present disclosure provides a film forming method of embedding a metal film in a recess, which is formed in a substrate and has an insulating film formed on a surface of the recess. The method includes: conformally forming a base film in the recess; etching the base film such that a surface of the insulating film formed on an upper portion of an inner wall of the recess is exposed and the base film remains on a bottom portion in the recess; and selectively growing the metal film on the base film remaining on the bottom portion in the recess.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a flowchart illustrating an example of a film forming method.

FIGS. 2A to 2D are sectional views illustrating steps of the example of the film forming method.

FIG. 3 is a schematic view illustrating a configuration example of a substrate processing system.

FIG. 4 is a schematic view illustrating a configuration example of a TiN film forming apparatus.

FIG. 5 is a schematic view illustrating a configuration example of a TiN film etching apparatus.

FIG. 6 is a view illustrating a configuration example of a tungsten film forming apparatus.

FIG. 7 is an explanatory view of an experimental procedure of a selective growth of a ruthenium film.

FIG. 8 is an SEM photograph showing a state in which a ruthenium film is selectively grown on a TiN film present on a bottom portion of a recess.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, non-restrictive exemplary embodiments of the present disclosure will be described with reference to the accompanying drawings. In all of the accompanying drawings, the same or corresponding members or components will be denoted by the same or corresponding reference numerals, and redundant descriptions will be omitted.

### [Film Forming Method]

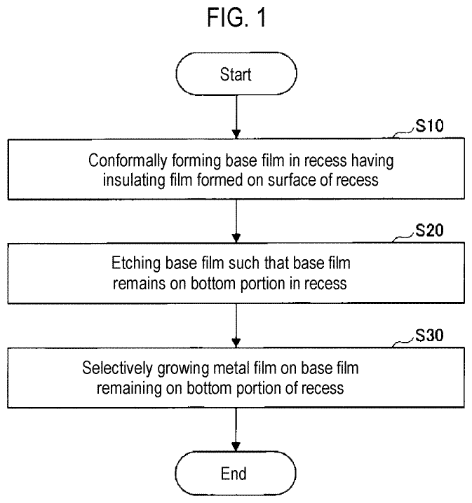

A film forming method according to an embodiment will be described. FIG. 1 is a flowchart illustrating an example of a film forming method.

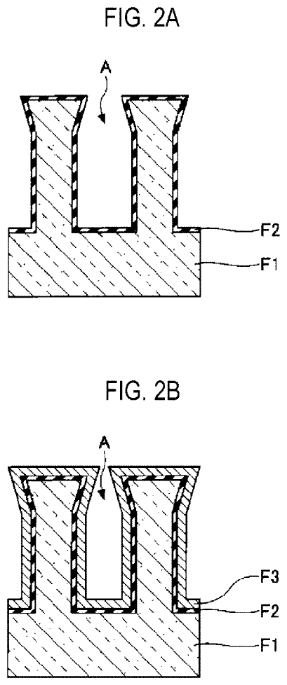

As illustrated in FIG. 1, the film forming method according to the embodiment is a method of embedding, with respect to a substrate in which a recess having an insulating film formed on a surface of the recess is formed, a metal film in the recess by executing step S10, step S20, and step S30 in this particular order. Step S10 is a step of conformally forming a base film in a recess having an insulating film formed on the surface of the recess. The wording “substrate in which a recess having an insulating film formed on a surface of the recess is formed” includes a case where a surface of a recess A formed in a substrate F1 is covered with an insulating film F2, as illustrated in FIGS. 2A to 2D, and a case where a recess is formed by a pattern of an insulating film formed on a substrate (not illustrated). Step S20 is a step of etching the base film such that the base film remains on a bottom portion in the recess. Step S30 is a step of selectively growing a metal film on the base film remaining on the bottom portion of the recess.

Respective steps will be described below with reference to FIGS. 2A to 2D. FIGS. 2A to 2D are sectional process views illustrating steps of the example of the film forming method.

With respect to the substrate F1 in which the recess A having the insulating film F2 formed on the surface of the recess is formed and which is prepared in advance (see FIG. 2A), step S10 is a step of conformally forming a base film F3 in the recess A (see FIG. 2B). In step S10, the base film F3 is conformally formed in the recess A by using, for example, an atomic layer deposition (ALD) method or a chemical vapor deposition (CVD) method. In some embodiments, the ALD method may be used so as to conformally form the base film F3 in the recess A even if the recess A has a high aspect ratio. The insulating film F2 may be, for example, a SiO₂ film or a SiN film. The base film F3 may be, for example, a TiN film, a TaN film, or a TiON film.

In the embodiment, the TiN film may be formed on the insulating film F2 by alternately repeating a supply of a titanium-containing gas and a supply of a nitrogen-containing gas in a depressurized state with a supply of a purge gas performed between the supply of the titanium-containing gas and the supply of the nitrogen-containing gas. As the titanium-containing gas, for example, a TiCl₄ gas, a TiBr₄ gas, a TiI₄ gas, tetrakis ethylmethylamido titanium (TEMAT), tetrakis dimethylamino titanium (TDMAT), or tetrakis diethylamino titanium (TDEAT) may be used. As the nitrogen-containing gas, for example, a NH₃ gas or monomethyl hydrazine (MMH) may be used. As the purge gas, for example, an inert gas such as a N₂ gas or Ar gas may be used. Further, the nitrogen-containing gas may be turned into a plasma.

Step S20 is a step of etching the base film F3 such that the surface of the insulating film F2 on an upper portion in an inner wall of the recess A is exposed and the base film F3 remains on a bottom portion in the recess A (see FIG. 2C). In step S20, the etching process may be performed in a supply rate limiting state. Thus, most of an etching gas is consumed in the upper portion of the inner wall of the recess A, and a small amount of the etching gas reaches the bottom portion of the recess A. Therefore, the base film F3 formed on the upper portion of the inner wall of the recess A is removed, and the base film F3 easily remains on the bottom portion of the recess A. The supply rate limiting state means a state in which a flow rate of the etching gas supplied to the process container is very small and the etching rate is mainly controlled by the supply amount of the etching gas. It is possible to implement the supply rate limiting state, for example, by reducing the supply amount of the etching gas and increasing a processing temperature.

In the embodiment, utilizing a plasma-less etching process using a halogen-containing gas, the base film F3 can be etched such that the surface of the insulating film F2 on the upper portion of the inner wall of the recess A is exposed and such that the base film F3 remains on the bottom portion in the recess A. As the halogen-containing gas a Cl₂ gas, a ClF₃ gas, a Br₂ gas, a HBr gas, an I₂ gas, a HI gas, a F₂ gas, or a NF₃ gas may be used. A plasma etching process may be used instead of the plasma-less etching process. When the plasma etching process is used the above-mentioned halogen-containing gas may be used, or a H₂ gas, an Ar gas, or the like may be used.

Step S30 is a step of selectively growing a metal film F4 on the base film F3 remaining on the bottom portion in the recess A (see FIG. 2D). Step S30 is performed, for example, by supplying a gas having an incubation time, which is shorter for the base film F3 than for the insulating film F2. For example, an ALD method or a CVD method may be used as long as the metal film F4 is selectively grown on the base film F3 remaining on the bottom portion of the recess A. The metal film F4 may be, for example, a tungsten film or a ruthenium film.

In the embodiment, the tungsten film may be formed on the base film F3 remaining on the bottom portion in the recess A by alternately repeating the supply of the tungsten-containing gas and the supply of the reducing gas with the supply of the purge gas performed between the supply of the tungsten-containing gas and the supply of the reducing gas. As the tungsten-containing gas, for example, a tungsten hexachloride gas such as a WCl₆ gas or WCl₅ gas or a tungsten fluoride gas such as a WF₆ gas may be used. As the reducing gas, for example, a H₂ gas or B₂H₆ gas may be used. The above-mentioned tungsten-containing gas has an incubation time shorter for the base film F3 than for the insulating film F2. For that reason, by using the above-mentioned tungsten-containing gas, it is possible to selectively grow the tungsten film on the base film F3.

In the embodiment, it is possible to selectively grow a ruthenium film on the base film F3 remaining on the bottom portion in the recess A through a thermal CVD method using a ruthenium-containing gas. As the ruthenium-containing gas, for example, Ru₃(CO)₁₂ may be used. The above-mentioned ruthenium-containing gas is a gas having an incubation time shorter for the base film F3 than for the insulating film F2. Therefore, by using the above-mentioned ruthenium-containing gas, it is possible to selectively grow the ruthenium film on the base film F3.

According to the above-described film forming method, the base film F3 is conformally formed in the recess A, and the base film F3 is etched such that the base film F3 on the upper portion of the inner wall of the recess A is removed and the base film F3 remains on the bottom portion in the recess A. Then, the metal film F4 is selectively grown on the base film F3 remaining on the bottom portion of the recess A. Thus, the metal film F4 can be grown in the recess A in a bottom-up fashion. For that reason, it is possible to embed the metal film F4 in the recess A without generating voids. In addition, it is possible to suppress adjacent patterns in the upper portion of the inner wall of the recess A from coming into contact with each other before the metal film F4 is embedded in the recess A. Therefore, pattern collapse that may occur when the metal film F4 is embedded in the recess A can be suppressed.

Steps S10, S20, and S30 may be performed consecutively in the same processing container, or may be performed in separate processing containers. Alternatively, two of the steps S10, S20, and S30 may be performed in the same processing container, and a remaining step may be performed in another processing container. However, when the steps are performed in separate processing containers, from the viewpoint of preventing oxidization of a film surface, steps S10, S20, and S30 may be performed in the processing containers connected to one another via a vacuum transfer chamber. In addition, when processing temperatures in the respective steps are different from one another, from the viewpoint of shortening times required for changing the processing temperatures, steps S10, S20, and S30 may be performed in separate processing containers connected via a vacuum transfer chamber.

### [Substrate Processing System]

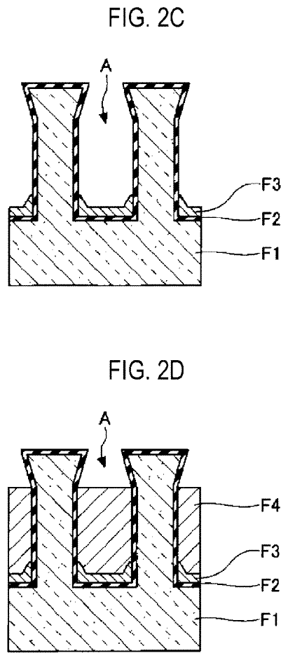

A substrate processing system for implementing the film forming method described above will be described with an example of a case where step S10, step S20, and step S30 are performed in separate processing containers connected via a vacuum transfer chamber. FIG. 3 is a schematic view illustrating a configuration example of a substrate processing system.

As illustrated in FIG. 3, the substrate processing system includes processing apparatuses 101 to 104, a vacuum transfer chamber 200, load-lock chambers 301 to 303, an atmospheric transfer chamber 400, and load ports 501 to 503, and an overall controller 600. However, the substrate processing system illustrated in FIG. 3 is an example, and the arrangement and number of the processing apparatuses, vacuum transfer chambers, load-lock chambers, atmospheric transfer chamber, and load ports are not limited to the illustrated example.

The processing apparatuses 101 to 104 are connected to the vacuum transfer chamber 200 via gate valves G11 to G14, respectively. The interiors of the processing apparatuses 101 to 104 are depressurized to a vacuum atmosphere, and various processes are performed on wafers W in the processing apparatuses 101 to 104. In the embodiment, the processing apparatus 101 is an apparatus for forming a TiN film, the processing apparatus 102 is an apparatus for etching the TiN film, and the processing apparatus 103 is an apparatus for forming a tungsten film. The processing apparatus 104 may be an apparatus which is the same as one of the processing apparatuses 101 to 103, or may be an apparatus that performs a separate process.

The interior of the vacuum transfer chamber 200 is depressurized to a vacuum atmosphere. A transfer mechanism 201 configured to transfer the wafers W in a depressurized state is installed in the vacuum transfer chamber 200. The transfer mechanism 201 transfers the wafers W with respect to the processing apparatuses 101 to 104 and the load-lock chambers 301 to 303. The transfer mechanism 201 has, for example, two independently movable transfer arms 202a and 202b. Alternatively, the transfer mechanism 201 may be configured to have a single transfer arm or three or more transfer arms.

The load-lock chambers 301 to 303 are connected to the vacuum transfer chamber 200 via gate valves G21 to G23, respectively, and connected to the atmospheric transfer chamber 400 via gate valves G31 to G33, respectively. The load-lock chambers 301 to 303 may be configured such that the interiors of the load-lock chambers 301 to 303 are switchable between an atmospheric atmosphere and a vacuum atmosphere.

The interior of the atmospheric transfer chamber 400 is kept to an atmospheric atmosphere, and, for example, a downflow of clean air is formed in the atmospheric transfer chamber 400. An aligner 401 configured to perform alignment of the wafers W is installed in the atmospheric transfer chamber 400. In addition, a transfer mechanism 402 is installed in the vacuum transfer chamber 400. The transfer mechanism 402 transfers the wafers W with respect to the load-lock chambers 301 to 303, the aligner 401, and carriers C disposed in the load ports 501 to 503 to be described later. The transfer mechanism 402 has, for example, a single transfer arm. Alternatively, the transfer mechanism 402 may be configured to have two or more transfer arms.

The load ports 501 to 503 are provided on a wall surface of a long side of the atmospheric transfer chamber 400. The carriers C, each of which accommodates the wafers W or is an empty carrier, are placed on the load ports 501 to 503. As the carriers C, for example, front opening unified pods (FOUPs) may be used.

The overall controller 600 controls respective components of the substrate processing system. For example, the overall controller 600 executes operation of the processing apparatuses 101 to 104, operation of the transfer mechanisms 201 and 402, opening and closing of the gate valves G11 to G14, G21 to G23, and G31 to G33, and switching of the atmospheres in the load-lock chambers 301 to 303. The overall controller 600 may be, for example, a computer.

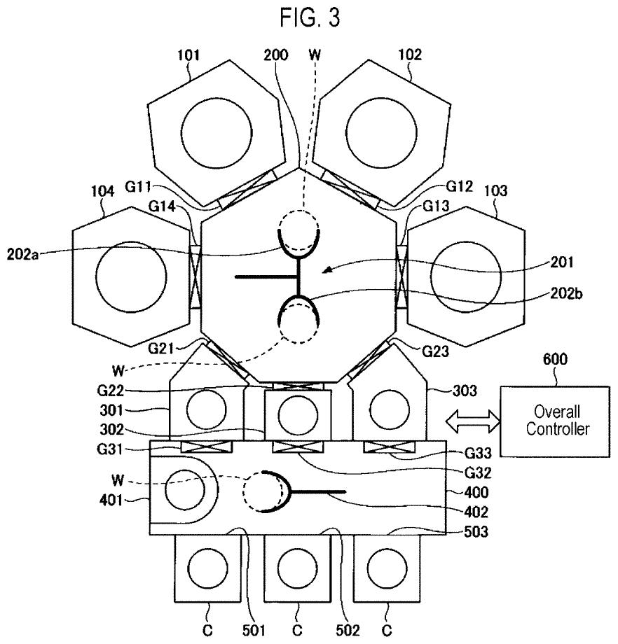

Next, a configuration example of the processing apparatus 101 will be described. The processing apparatus 101 is an example of a first processing apparatus that forms a TiN film in the depressurized processing container through an ALD method or a CVD method. FIG. 4 is a schematic view illustrating a configuration example of a TiN film forming apparatus.

As illustrated in FIG. 4, the processing apparatus 101 includes a processing container 1, a stage 2, a shower head 3, an exhauster 4, a gas supply mechanism 5, and a controller 9.

The processing container 1 is formed of metal such as aluminum, and has a substantially cylindrical shape. The processing container 1 accommodates the wafer W. A loading/unloading port 11 through which the wafer W is loaded and unloaded is formed in a side wall of the processing container 1. The loading/unloading port 11 is opened and closed by a gate valve 12. An annular exhaust duct 13 having a rectangular section is provided above a main body of the processing container 1. The exhaust duct 13 has a slit 13a formed along an inner peripheral surface of the exhaust duct 13. An exhaust port 13b is formed in an outer wall of the exhaust duct 13. A ceiling wall 14 is provided on an upper surface of the exhaust duct 13 so as to close an upper opening of the processing container 1. A space between the exhaust duct 13 and the ceiling wall 14 is hermetically sealed with a seal ring 15.

The stage 2 horizontally supports the wafer W in the processing container 1. The stage 2 is formed in a disk-like shape and has a size corresponding to that of the wafer W. The stage 2 is supported by a support 23. The stage 2 is formed of ceramic such as MN or metal such as aluminum or nickel alloy, and a heater 21 configured to heat the wafer W is embedded in the stage 2. The heater 21 is fed with power from a heater power supply (not illustrated) and generates heat. A temperature of the wafer W is controlled to a predetermined temperature by controlling an output of the heater 21 based on a temperature signal of a thermocouple (not illustrated) provided in the vicinity of an upper surface of the stage 2. The stage 2 is provided with a cover 22, which is formed of ceramic such as alumina and covers an outer peripheral area of the upper surface of the stage 2 and a lateral surface of the stage 2.

The support 23 configured to support the stage 2 is provided on a bottom surface of the stage 2. The support 23 extends downward from a center of the bottom surface of the stage 2 to pass through a hole formed in a bottom wall of the processing container 1 and reach below the processing container 1. A lower end of the support 23 is connected to a lifting mechanism 24. The stage 2 is moved upward and downward between a processing position illustrated in FIG. 4 and a transfer position, which is indicated by a double-dot chain line below the processing position and in which the wafer W is transferred, by the lifting mechanism 24 via the support 23. A flange 25 is provided in the support 23 below the processing container 1, and a bellows 26, which partitions the internal atmosphere of the processing container 1 from the external atmosphere and expands and contracts in response to the upward and downward movement of the stage 2, is provided between the bottom surface of the processing container 1 and the flange 25.

Three wafer support pins 27 protruding upward from a lifting plate 27a are provided in the vicinity of the bottom surface of the processing container 1 (only two of the wafer support pins 27 are illustrated). The wafer support pins 27 are moved upward and downward by a lifting mechanism 28, which is provided below the processing container 1, via the lifting plate 27a. The wafer support pins 27 are configured to protrude and retract with respect to the upper surface of the stage 2 by being inserted through the through holes 2a formed in the stage 2 located at the transfer position. By moving the wafer support pins 27 upward and downward, the wafer W is delivered between a transfer mechanism (not illustrated) and the stage 2.

The shower head 3 supplies a processing gas to the interior of the processing container 1 in the form of a shower. The shower head 3 is formed of metal. The shower head 3 faces the stage 2, and has a diameter substantially equal to that of the stage 2. The shower head 3 has a main body 31 fixed to the ceiling wall 14 of the processing container 1 and a shower plate 32 connected to a lower portion of the main body 31. A gas diffusion space 33 is formed between the main body 31 and the shower plate 32. The gas diffusion space 33 is in communication with gas introduction holes 36 and 37 passing through the center portions of the main body 31 and the ceiling wall 14 of the processing container 1. An annular protrusion 34 protruding downward is formed on a peripheral edge of the shower plate 32. Gas ejection holes 35 are formed in a flat surface of the shower plate 32 inward than the annular protrusion 34. In a state in which the stage 2 is located at the processing position, a processing space 38 is formed between the stage 2 and the shower plate 32, and the upper surface of the cover 22 and the annular protrusion 34 come close to each other so as to form an annular gap 39.

The exhauster 4 evacuates the interior of the processing container 1. The exhauster 4 includes an exhaust pipe 41 connected to the exhaust port 13b, and an exhaust mechanism 42 connected to the exhaust pipe 41 and having, for example, a vacuum pump or a pressure control valve. During the processing, a gas in the processing container 1 reaches the exhaust duct 13 through the slit 13a, and is exhausted from the exhaust duct 13 by the exhaust mechanism 42 through the exhaust pipe 41.

The gas supply mechanism 5 supplies the processing gas to interior of the processing container 1. The gas supply mechanism 5 includes a TiCl₄ gas source 51a, a N₂ gas source 53a, a NH₃ gas source 55a, and a N₂ gas source 57a.

The TiCl₄ gas source 51a supplies a TiCl₄ gas as a titanium-containing gas to the processing container 1 through a gas supply line 51b. In the gas supply line 51b, a flow rate controller 51c, a storage tank 51d, and a valve 51e is installed in this order from an upstream side. A downstream side of the valve 51e of the gas supply line 51b is connected to the gas introduction hole 36. The TiCl₄ gas supplied from the TiCl₄ gas source 51a is temporarily stored and boosted to a predetermined pressure in the storage tank 51d before being supplied to the processing container 1, and is then supplied to the processing container 1. A supply and stop of the TiCl₄ gas from the storage tank 51d to the processing container 1 are performed by opening and closing the valve 51e. By temporarily storing the TiCl₄ gas in the storage tank 51d as described above, it is possible to stably supply the TiCl₄ gas to the processing container 1 at a relatively large flow rate.

The N₂ gas source 53a supplies a N₂ gas as a carrier gas to the processing container 1 through a gas supply line 53b. The N₂ gas serves as a purge gas. In the gas supply line 53b, a flow rate controller 53c, a valve 53e, and an orifice 53f is installed in this order from an upstream side. A downstream side of the orifice 53f of the gas supply line 53b is connected to the gas supply line 51b. The N₂ gas supplied from the N₂ gas source 53a is continuously supplied to the processing container 1 during a film formation on the wafer W. A supply and stop of the N₂ gas from the N₂ gas source 53a to the processing container 1 are performed by opening and closing the valve 53e. Although the TiCl₄ gas is supplied to the gas supply line 51b at the relatively large flow rate by the storage tank 51d, the gases supplied to the gas supply line 51b are prevented from flowing back to the N₂ gas supply line 53b by the orifice 53f. Alternatively, the purge gas supply line and the carrier gas supply line may be individually provided.

The NH₃ gas source 55a supplies a NH₃ gas as a nitrogen-containing gas to the processing container 1 through a gas supply line 55b. In the gas supply line 55b, a flow rate controller 55c, a storage tank 55d, and a valve 55e are installed in this order from an upstream side. A downstream side of the valve 55e of the gas supply line 55b is connected to the gas introduction hole 37. The NH₃ gas supplied from the NH₃ gas source 55a is temporarily stored and boosted to a predetermined pressure in the storage tank 55d before being supplied to the processing container 1, and is then supplied to the processing container 1. A supply and stop of the NH₃ gas from the storage tank 55d to the processing container 1 are performed by opening and closing the valve 55e. By temporarily storing the NH₃ gas in the storage tank 55d as described above, it is possible to stably supply the NH₃ gas to the processing container 1 at a relatively large flow rate.

The N₂ gas source 57a supplies N₂ gas as a carrier gas to the processing container 1 through a gas supply line 57b. The N₂ gas serves as a purge gas. In the gas supply line 57b, a flow rate controller 57c, a valve 57e, and an orifice 57f are installed in this order from an upstream side. A downstream side of the orifice 57f of the gas supply line 57b is connected to the gas supply line 55b. The N₂ gas supplied from the N₂ gas source 57a is continuously supplied to the processing container 1 during the film formation on the wafer W. A supply and stop of the N₂ gas from the N₂ gas source 57a to the processing container 1 are performed by opening and closing the valve 57e. Although the NH₃ gas is supplied to the gas supply line 55b at the relatively large flow rate by the storage tank 55d, the gases supplied to the gas supply line 55b are prevented from flowing back to the N₂ gas supply line 57b by the orifice 57f. Alternatively, the purge gas supply line and the carrier gas supply line may be individually provided.

The controller 9 is, for example, a computer, and includes a central processing unit (CPU), a random access memory (RAM), a read only memory (ROM), an auxiliary storage device, and the like. The CPU operates based on a program stored in the ROM or the auxiliary storage device, and controls the operation of the processing apparatus 101. The controller 9 may be provided either inside or outside the processing apparatus 101. In a case in which the controller 9 is provided outside the processing apparatus 101, the controller 9 can control the processing apparatus 101 through a wired or wireless communication mechanism.

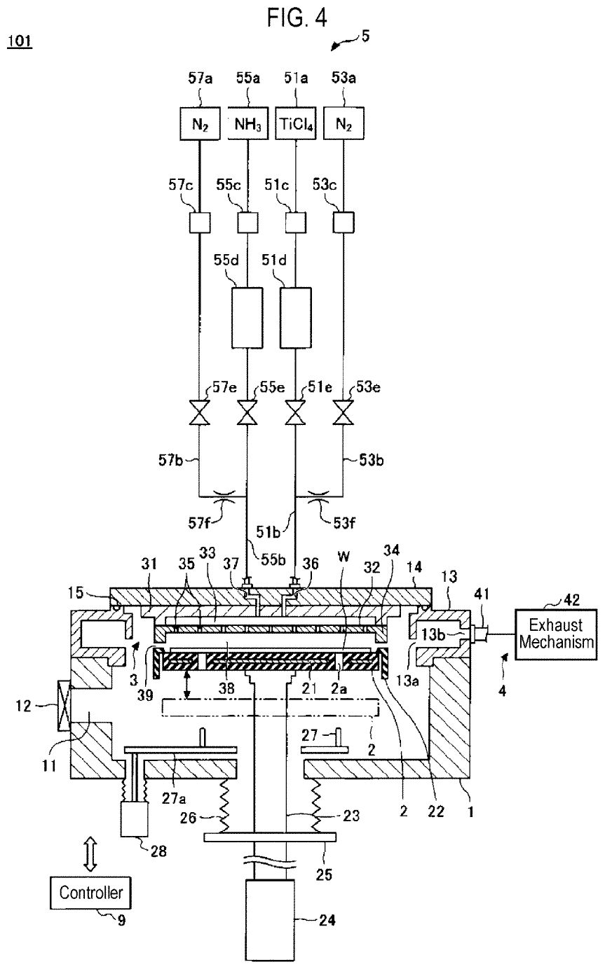

Next, a configuration example of the processing apparatus 102 will be described. The processing apparatus 102 is an example of a second processing apparatus that etches the TiN film in the depressurized processing container. FIG. 5 is a schematic view illustrating a configuration example of a TiN film etching apparatus.

As illustrated in FIG. 5, the processing apparatus 102 differs from the processing apparatus 101 in that the processing apparatus 102 has a gas supply mechanism 5A instead of the gas supply mechanism 5 in the processing apparatus 101. Since the processing apparatus 102 is the same as the processing apparatus 101 in the remaining features, differences from the processing apparatus 101 will be mainly described.

The gas supply mechanism 5A further includes a Cl2 gas source 52a compared with the gas supply mechanism 5 in the processing apparatus 101. The configurations of the TiCl₄ gas source 51a, the N₂ gas source 53a, the NH₃ gas source 55a, and the N₂ gas source 57a are the same as the processing apparatus 101.

The Cl₂ gas source 52a supplies a Cl₂ gas as an etching gas to the processing container 1 through a gas supply line 52b. In the gas supply line 52b, a flow rate controller 52c, a valve 52e, and an orifice 54f are installed in this order from an upstream side. A downstream side of the orifice 52f of the gas supply line 52b is connected to the gas supply line 51b. A supply and stop of the Cl₂ gas from the Cl₂ gas source 52a to the processing container 1 are performed by opening and closing the valve 52e. Although the TiCl₄ gas is supplied to the gas supply line 516 at the relatively large flow rate by the storage tank 51d, the gases supplied to the gas supply line 516 are prevented from flowing back to the Cl₂ gas supply line 52b by the orifice 52f.

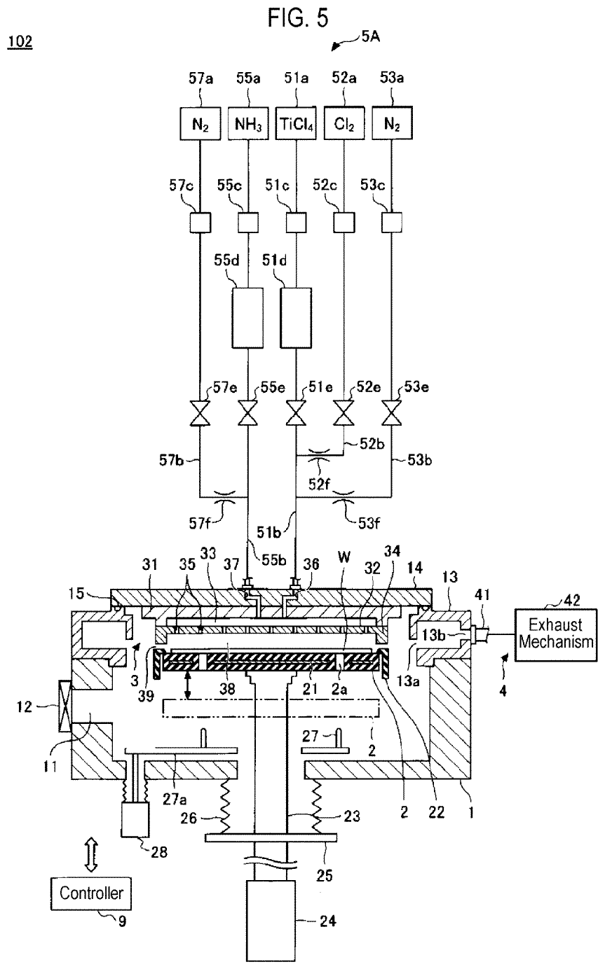

Next, a configuration example of the processing apparatus 103 will be described. The processing apparatus 103 is an example of a third processing apparatus that forms a tungsten film in the depressurized processing container through an ALD method. FIG. 6 is a view illustrating a configuration example of a tungsten film forming apparatus.

As illustrated in FIG. 6, the processing apparatus 103 differs from the processing apparatus 101 in that the processing apparatus 103 has a gas supply mechanism 6 instead of the gas supply mechanism 5 in the processing apparatus 101. Since the processing apparatus 103 is the same as the processing apparatus 101 in the remaining features, differences from the processing apparatus 101 will be mainly described.

The gas supply mechanism 6 supplies a processing gas to the processing container 1. The gas supply mechanism 6 includes a WCl₆ gas source 61a, a N₂ gas source 62a, a N₂ gas source 63a, a H₂ gas source 64a, a N₂ gas source 66a, a N₂ gas source 67a, and a H₂ gas source 68a.

The WCl₆ gas source 61a supplies a WCl₆ gas to the processing container 1 through a gas supply line 61b. In the gas supply line 61b, a flow rate controller 61c, a storage tank 61d, and a valve 61e are installed in this order from an upstream side. A downstream side of the valve 61e of the gas supply line 61b is connected to the gas introduction hole 36. The WCl₆ gas supplied from the WCl₆ gas source 61a is temporarily stored and boosted to a predetermined pressure in the storage tank 61d before being supplied to the processing container 1, and is then supplied to the processing container 1. A supply and stop of the WCl₆ gas from the storage tank 61d to the processing container 1 are performed by opening and closing the valve 61e. By temporarily storing the WCl₆ gas in the storage tank 61d as described above, it is possible to stably supply the WCl₆ gas to the processing container 1 at a relatively large flow rate.

The N₂ gas source 62a supplies a N₂ gas as a purge gas to the processing container 1 through a gas supply line 62b. In the gas supply line 62b, a flow rate controller 62c, a storage tank 62d, and a valve 62e are installed in this order from an upstream side. A downstream side of the valve 62e of the gas supply line 62b is connected to the gas supply line 61b. The N₂ gas supplied from the N₂ gas source 62a is temporarily stored and boosted to a predetermined pressure in the storage tank 62d before being supplied to the processing container 1, and is then supplied to the processing container 1. A supply and stop of the N₂ gas from the storage tank 62d to the processing container 1 are performed by opening and closing the valve 62e. By temporarily storing the N₂ gas in the storage tank 62d as described above, it is possible to stably supply the N₂ gas to the processing container 1 at a relatively large flow rate.

The N₂ gas source 63a supplies a N₂ gas as a carrier gas to the processing container 1 through a gas supply line 63b. In the gas supply line 63b, a flow rate controller 63c, a valve 63e, and an orifice 63f are installed in this order from an upstream side. A downstream side of the orifice 63f of the gas supply line 63b is connected to the gas supply line 61b. The N₂ gas supplied from the N₂ gas source 63a is continuously supplied to the processing container 1 during the film formation on the wafer W. A supply and stop of the N₂ gas from the N₂ gas source 63a to the processing container 1 are performed by opening and closing the valve 63e. Although the gases are supplied to the gas supply lines 61b and 62b at the relatively large flow rates by the storage tanks 61d and 62d, the gases supplied to the gas supply lines 61b and 62b are prevented from flowing back to the N₂ gas supply line 63b by the orifice 63f.

The H₂ gas source 64a supplies a H₂ gas as a reducing gas to the processing container 1 through a gas supply line 64b. In the gas supply line 64b, a flow rate controller 64c, a valve 64e, and an orifice 64f are installed in this order from an upstream side. A downstream side of the orifice 64f of the gas supply line 64b is connected to the gas introduction hole 37. The H₂ gas supplied from the H₂ gas source 64a is continuously supplied to the processing container 1 during the film formation on the wafer W. A supply and stop of the H₂ gas from the H₂ gas source 64a to the processing container 1 are performed by opening and closing the valve 64e. Although the gases are supplied to gas supply lines 66b and 68b at relatively large flow rates by storage tanks 66d and 68d, the gases supplied to the gas supply lines 66b and 68b are prevented from flowing back to the H₂ gas supply line 64b by the orifice 64f.

The N₂ gas source 66a supplies a N₂ gas as a purge gas to the processing container 1 through the gas supply line 66b. In the gas supply line 66b, a flow rate controller 66c, the storage tank 66d, and a valve 66e are installed in this order from an upstream side. A downstream side of the valve 66e of the gas supply line 66b is connected to the gas supply line 64b. The N₂ gas supplied from the N₂ gas source 66a is temporarily stored and boosted to a predetermined pressure in the storage tank 66d before being supplied to the processing container 1, and is then supplied to the processing container 1. A supply and stop of the N₂ gas from the storage tank 66d to the processing container 1 are performed by opening and closing the valve 66e. By temporarily storing the N₂ gas in the storage tank 66d as described above, it is possible to stably supply the N₂ gas to the processing container 1 at the relatively large flow rate.

The N₂ gas source 67a supplies a N₂ gas as a carrier gas to the processing container 1 through a gas supply line 67b. In the gas supply line 67b, a flow rate controller 67c, a valve 67e, and an orifice 67f are installed in this order from an upstream side. A downstream side of the orifice 67f of the gas supply line 67b is connected to the gas supply line 64b. The N₂ gas supplied from the N₂ gas source 67a is continuously supplied to the processing container 1 during the film formation on the wafer W. A supply and stop of the N₂ gas from the N₂ gas source 67a to the processing container 1 are performed by opening and closing the valve 67e. Although the gases are supplied to the gas supply lines 66b and 68b at the relatively large flow rates by the storage tanks 66d and 68d, the gases supplied to the gas supply lines 66b and 68b are prevented from flowing back to the N₂ gas supply line 67b by the orifice 67f.

The H₂ gas source 68a supplies a H₂ gas as a reducing gas to the processing container 1 through the gas supply line 68b. In the gas supply line 68b, a flow rate controller 68c, the storage tank 68d, and a valve 68e are installed in this order from an upstream side. A downstream side of the valve 68e of the gas supply line 68b is connected to the gas supply line 64b. The H₂ gas supplied from the H₂ gas source 68a is temporarily stored and boosted to a predetermined pressure in the storage tank 68d before being supplied to the processing container 1, and is then supplied to the processing container 1. A supply and stop of the H₂ gas from the storage tank 68d to the processing container 1 are performed by opening and closing the valve 68e. By temporarily storing the H₂ gas in the storage tank 68d as described above, it is possible to stably supply the H₂ gas to the processing container 1 at the relatively large flow rate.

### [Operation of Substrate Processing System]

Next, an example of an operation of the substrate processing system will be described with reference to FIG. 3.

First, the overall controller 600 controls the transfer mechanism 402 to transfer the wafer W accommodated in, for example, the carrier C disposed in the load port 501 to the aligner 401. The wafer W has a recess having an insulating film formed on the surface of the recess. The overall controller 600 operates the aligner 401 to perform an alignment of the wafer W. Subsequently, the overall controller 600 opens the gate valve G31, and controls the transfer mechanism 402 to transfer the wafer W from the aligner 401 to the load-lock chamber 301. The overall controller 600 closes the gate valve G31, and sets the interior of the load-lock chamber 301 to a vacuum atmosphere. In a case in which the alignment of the wafer W is unnecessary, the overall controller 600 controls the transfer mechanism 402 to transfer the wafer W accommodated in the carrier C of the load port 501 to the load-lock chamber 301 without transferring the wafer W to the aligner 401.

The overall controller 600 opens the gate valves G11 and G21, and controls the transfer mechanism 201 to transfer the wafer W in the load-lock chamber 301 to the processing apparatus 101. The overall controller 600 closes the gate valves G11 and G21, and operates the processing apparatus 101. Thus, the processing apparatus 101 performs, on the wafer W, a process for conformally forming a TiN film in the recess.

Subsequently, the overall controller 600 opens the gate valves G11 and G12, and controls the transfer mechanism 201 to transfer the wafer W processed by the processing apparatus 101 to the processing apparatus 102. The overall controller 600 closes the gate valves G11 and G12, and operates the processing apparatus 102. Thus, the processing apparatus 102 performs, on the wafer W, a process for etching the TiN film such that the surface of the insulating film on the upper portion of the inner wall of the recess is exposed and the TiN film remains on the bottom portion of the recess.

Subsequently, the overall controller 600 opens the gate valves G12 and G13, and controls the transfer mechanism 201 to transfer the wafer W processed by the processing apparatus 102 to the processing apparatus 103. The overall controller 600 closes the gate valves G12 and G13, and operates the processing apparatus 103. Thus, the processing apparatus 103 performs, on the wafer W, a process for selectively growing a tungsten film on the TiN film remaining on the bottom portion of the recess.

Subsequently, the overall controller 600 opens the gate valves G13 and G23, and controls the transfer mechanism 201 to transfer the wafer W processed by the processing apparatus 103 to the load-lock chamber 303. The overall controller 600 closes the gate valves G13 and G23, and sets the interior of the load-lock chamber 303 to an atmospheric atmosphere. The overall controller 600 opens the gate valve G33, and controls the transfer mechanism 402 to transfer the wafer W in the load-lock chamber 303 to the carrier C in the load port 503.

As described above, according to the substrate processing system illustrated in FIG. 3, the wafer W is not exposed to the atmospheric atmosphere while the wafer W is processed by the processing apparatuses 101 to 103. In other words, with the substrate processing system illustrated in FIG. 3, it is possible to perform predetermined processes on the wafer W without breaking vacuum.

Hereinafter, operations of the processing apparatuses 101 to 103 (steps S10, S20, and S30) will be described with reference to FIGS. 4 to 6.

### (Operation of Processing Apparatus 101)

Referring to FIG. 4, the operation of the processing apparatus 101 will be described. First, in a state where the valves 51e, 53e, 55e, and 57e are closed, the gate valve 12 is opened, and the wafer W is transferred to the processing container 1 and placed on the stage 2 at the transfer position by a transfer mechanism (not illustrated). After the transfer mechanism is retracted from the interior of the processing container 1, the gate valve 12 is closed. The wafer W is heated to a predetermined temperature by the heater 21 of the stage 2, and the stage 2 is moved upward to the processing position so as to form the processing space 38. In addition, the pressure in the processing container 1 is adjusted to a predetermined pressure by the pressure control valve (not illustrated) of the exhaust mechanism 42.

Subsequently, the valves 53e and 57e are opened, and a carrier gas (N₂ gas) is supplied from the N₂ gas sources 53a and 57a to the gas supply lines 53b and 57b, respectively. In addition, a TiCl₄ gas is supplied to the gas supply line 51b from the TiCl₄ gas source Ma, and a NH₃ gas is supplied to the gas supply line 55b from the NH₃ gas source 55a. At this time, since the valves 51e and 55e are kept closed, the TiCl₄ gas and the NH₃ are stored in the storage tanks 51d and 55d, respectively, and the interiors of the storage tanks 51d and 55d are boosted.

Next, the valve 51e is opened, and the TiCl₄ gas stored in the storage tank 51d is supplied to the processing container 1 so as to be adsorbed on the surface of the wafer W.

After a predetermined time elapses after the valve 51e is opened, the valve 51e is closed so as to stop the supply of the TiCl₄ gas to the processing container 1. At this time, since the carrier gas is supplied to the processing container 1, the TiCl₄ gas remaining in the processing container 1 is discharged to the exhaust pipe 41, so that the interior of the processing container 1 is replaced from a TiCl₄ gas atmosphere to a N₂ gas atmosphere. Meanwhile, by closing the valve 51e, the TiCl₄ gas supplied from the TiCl₄ gas source 51a to the gas supply line 51b is stored in the storage tank 51d, and the interior of the storage tank 51d is boosted.

After a predetermined time elapses after the valve 51e is closed, the valve 55e is opened. As a result, the NH₃ gas stored in the storage tank 55d is supplied to the processing container 1, so that the TiCl₄ gas adsorbed on the surface of the wafer W is reduced.

After a predetermined time elapses after the valve 55e is opened, the valve 55e is closed so as to stop the supply of the NH₃ gas to the processing container 1. At this time, since the carrier gas is supplied to the processing container 1, the NH₃ gas remaining in the processing container 1 is discharged to the exhaust pipe 41, so that the interior of the processing container 1 is replaced from an NH₃ gas atmosphere to an N₂ gas atmosphere. Meanwhile, by closing the valve 55e, the NH₃ gas supplied from the NH₃ gas source 55a to the gas supply line 55b is stored in the storage tank 55d, and the interior of the storage tank 55d is boosted.

By performing the above cycle once, a thin TiN unit film is formed on the surface of the TiN film. Then, by repeating the cycle multiple times, a TiN film having a desired thickness is formed. Thereafter, the wafer W is unloaded from the processing container 1 in the reverse order of loading the wafer W to the processing container 1.

An example of a film forming condition for conformally forming a TiN film in a recess using the processing apparatus 101 is as follows.

### <Film Forming Condition>

Wafer temperature: 460 to 650 degrees C.
Pressure in processing container: 3 to 5 Torr (400 to 667 Pa)
Flow rate of TiCl₄ gas: 150 to 300 sccm
Flow rate of NH₃ gas: 3800 to 7000 sccm
Flow rate of carrier gas (N₂ gas): 1000 to 6000 sccm

Alternatively, the TiN film may be conformally formed in the recess by providing a high-frequency power source in the processing apparatus 101 and alternately repeating a supply of a mixed gas of TDMAT and Ar and a supply of a mixed gas of NH₃, Ar, and H₂ with a supply of the purge gas performed between the supplies of the mixed gases. At this time, the mixed gas of NH₃, Ar, and H₂ may be turned into a plasma. An example of a film forming condition in this case is as follows.

### <Film Forming Condition>

Wafer temperature: 200 to 400 degrees C.
Pressure in processing container: 1 to 5 Torr (133 to 667 Pa)
TDMAT/Ar flow rate: 50 to 200 sccm/1000 to 6000 sccm
NH₃/Ar/H₂ flow rate: 500 to 1500 sccm/500 to 5000 sccm/500 to 5000 sccm
High-frequency power: 300 to 1500 W

### (Operation of Processing Apparatus 102)

Referring to FIG. 5, the operation of the processing apparatus 102 will be described. First, in a state where the valves 51e, 52e, 53e, 55e, and 57e are kept closed, the gate valve 12 is opened, and the wafer W is transferred to the processing container 1 and placed on the stage 2 at the transfer position by a transfer mechanism (not illustrated). After the transfer mechanism is retracted from the interior of the processing container 1, the gate valve 12 is closed. The wafer W is heated to a predetermined temperature by the heater 21 of the stage 2, and the stage 2 is moved upward to the processing position so as to form the processing space 38. In addition, the pressure in the processing container 1 is adjusted to a predetermined pressure by the pressure control valve (not illustrated) of the exhaust mechanism 42.

Subsequently, the valves 53e and 57e are opened, and a predetermined flow rate of carrier gas (N₂ gas) is supplied from the N₂ gas sources 53a and 57a to the gas supply lines 53b and 57b, respectively. In addition, the valve 52e is opened, and Cl₂ gas is supplied from the Cl₂ gas source 52a to the gas supply line 52b. Thus, the Cl₂ gas is supplied to the processing container 1, and the TiN film is etched. At this time, the TiN film is etched such that the TiN film on the upper portion of the inner wall of the recess is removed, and the TiN film remains on the bottom portion in the recess.

After a predetermined time elapses after the valve 52e is opened, the valve 52e is closed so as to stop the supply of the Cl₂ gas to the processing container 1. At this time, since the carrier gas is supplied to the processing container 1, the Cl₂ gas remaining in the processing container 1 is discharged to the exhaust pipe 41, so that the interior of the processing container 1 is replaced from a Cl₂ gas atmosphere to a N₂ gas atmosphere.

After a predetermined time elapses after the valve 52e is closed, the valves 53e and 57e are closed so as to stop the supply of the carrier gas to the processing container 1. Thereafter, the wafer W is unloaded from the processing container 1 in the reverse order of loading the wafer W to the processing container 1.

An etching condition in a case where the TiN film is etched using the processing apparatus 102 such that the surface of the insulating film on the upper portion of the inner wall of the recess is exposed and the TiN film remains on the bottom portion in the recess remains is as follows.

### <Etching Condition>

Wafer temperature: 100 to 300 degrees C.
Pressure in processing container: 0.5 to 5 Torr (67 to 667 Pa)
Flow rate of Cl₂ gas: 30 to 1000 sccm
Flow rate of carrier gas (N₂ gas): 1000 to 6000 sccm

Alternatively, the TiN film may be etched by providing a ClF₃ gas source as the gas supply mechanism 5A and supplying a ClF₃ gas to the processing container 1, such that the surface of the insulating film on the upper portion of the inner wall of the recess is exposed and the TiN film remains on the bottom portion of the recess. An example of an etching condition in this case is as follows.

### <Etching Condition>

Wafer temperature: 100 to 200 degrees C.
Pressure in processing container: 0.5 to 5 Torr (67 to 667 Pa)
Flow rate of ClF₃ gas: 5 to 500 sccm
Flow rate of carrier gas (N₂ gas): 1000 to 6000 sccm

### (Operation of Processing Apparatus 103)

Referring to FIG. 6, the operation of the processing apparatus 103 will be described. First, in a state where the valves 61e to 64e and the valves 66e to 68e are kept closed, the gate valve 12 is opened, and the wafer W is transferred to the processing container 1 and placed on the stage 2 at the transfer position by a transfer mechanism (not illustrated). After the transfer mechanism is retracted from the interior of the processing container 1, the gate valve 12 is closed. The wafer W is heated to a predetermined temperature by the heater 21 of the stage 2, and the stage 2 is moved upward to the processing position so as to form the processing space 38. In addition, the pressure in the processing container 1 is adjusted to a predetermined pressure by the pressure control valve (not illustrated) of the exhaust mechanism 42.

Subsequently, the valves 63e and 67e are opened, and a carrier gas (N₂ gas) is supplied from the N₂ gas sources 63a and 67a to the gas supply lines 63b and 67b, respectively. In addition, the valve 64e is opened, and a H₂ gas is supplied from the H₂ gas source 64a to the gas supply line 64b. In addition, a WCl₆ gas and a H₂ gas are supplied from the WCl₆ gas source 61a and the H₂ gas source 68a to the gas supply lines 61b and 68b, respectively. At this time, since the valves 61e and 68e are closed, the WCl₆ gas and the H₂ gas are stored in the storage tanks 61d and 68d, respectively, and the interiors of the storage tanks 61d and 68d are boosted.

Subsequently, the valve 61e is opened, and the WCl₆ gas stored in the storage tank 61d is supplied to the processing container 1 and is adsorbed on the surface of the wafer W. In addition, in parallel with the supply of the WCl₆ gas to the processing container 1, the purge gases (N₂ gases) is supplied from the N₂ gas sources 62a and 66a to the gas supply lines 62b and 66b, respectively. At this time, by closing the valves 62e and 66e, the purge gases are stored in the storage tanks 62d and 66d, and the interiors of the storage tanks 62d and 66d are boosted.

After a predetermined time elapses after the valve 61e is opened, the valve 61e is closed and the valves 62e and 66e are opened. Therefore, the supply of the WCl₆ gas to the processing container 1 is stopped, and the purge gases stored in each of the storage tanks 62d and 66d are supplied to the processing container 1. At this time, since the purge gases are supplied from the storage tanks 62d and 66d in the boosted states, the purge gases are supplied to the processing container 1 at a relatively large flow rate, for example, at a flow rate larger than a flow rate of the carrier gas. Therefore, the WCl₆ gas remaining in the processing container 1 is rapidly discharged to the exhaust pipe 41, and the interior of the processing container 1 is replaced from a WCl₆ gas atmosphere to an atmosphere containing the H₂ gas and the N₂ gas in a short time. Meanwhile, by closing the valve 61e, the WCl₆ gas supplied from the WCl₆ gas source 61a to the gas supply line 61b is stored in the storage tank 61d, and the interior of the storage tank 61d is boosted.

After a predetermined time elapses after the valves 62e and 66e are opened, the valves 62e and 66e are closed and the valve 68e is opened. As a result, the supply of the purge gases to the processing container 1 is stopped, and the H₂ gas stored in the storage tank 68d is supplied to the processing container 1, so that the WF₆ gas adsorbed to the surface of the wafer W is reduced. At this time, by closing the valves 62e and 66e, the purge gases supplied from the N₂ gas sources 62a and 66a to the gas supply lines 62b and 66b, respectively, are stored in the storage tanks 62d and 66d, and the interiors of the storage tanks 62d and 66d are boosted.

After a predetermined time elapses after the valve 68e is opened, the valve 68e is closed and the valves 62e and 66e are opened. As a result, the supply of the H₂ gas to the processing container 1 is stopped, and the purge gases stored in the storage tanks 62d and 66d are supplied to the processing container 1. At this time, since the purge gases are supplied from the storage tanks 62d and 66d in the boosted state, the purge gases are supplied to the processing container 1 at a relatively large flow rate, for example, at a flow rate larger than the flow rate of the carrier gas. Therefore, the H₂ gas remaining in the processing container 1 is rapidly discharged to the exhaust pipe 41, and the interior of the processing container 1 is replaced from the H₂ gas atmosphere to an atmosphere containing the H₂ gas and the N₂ gas in a short time. Meanwhile, by closing the valve 68e, the H₂ gas supplied from the H₂ gas source 68a to the gas supply line 68b is stored in the storage tank 68d, and the interior of the storage tank 68d is boosted.

By performing the above cycle once, a thin tungsten unit film is formed on the surface of the TiN film. Then, by repeating the cycle multiple times, a tungsten film having a desired thickness is formed. At this time, since the TiN film on the upper portion of the inner wall of the recess is removed and the TiN film remains on the bottom portion in the recess, the tungsten film is selectively grown on the TiN film remaining on the bottom portion in the recess. Thus, the tungsten film can be grown in the recess in a bottom-up fashion. For that reason, it is possible to embed a metal film in the recess without generating voids. In addition, it is possible to suppress adjacent patterns in the upper portion of the inner wall of the recess A from coming into contact with each other before the metal film is embedded in the recess. Therefore, pattern collapse that may occur when embedding the metal film in the recess can be suppressed. After embedding the tungsten film in the recess, the wafer W is unloaded from the processing container 1 in the reverse order of loading the wafer W to the processing container 1.

A film forming condition where a tungsten film is selectively grown on a TiN film remaining on the bottom portion in the recess using the processing apparatus 103 is as follows.

### <Film Forming Condition>

Wafer temperature: 450 to 650 degrees C.
Pressure in processing container: 15 to 40 Torr (2.0 to 5.3 kPa)
Flow rate of WCl₆ gas: 3 to 30 sccm
Flow rate of H₂ gas: 1000 to 9000 sccm
Flow rate of carrier gas (N₂ gas): 1000 to 8000 sccm

Alternatively, a ruthenium film may be selectively grown on the TiN film remaining on the bottom portion in the recess through a thermal CVD method using a Ru₃(CO)₁₂ gas, by providing a Ru₃(CO)₁₂ gas supply mechanism as the gas supply mechanism 6. The Ru3(CO12) gas supply mechanism includes a source container configured to accommodate and heat Ru₃(CO)₁₂ in a solid state, and a carrier gas supply pipe configured to supply a CO gas as a carrier to the source container. An example of a film forming condition in this case is as follows.

### <Film Forming Condition>

Wafer temperature: 100 to 250 degrees C.
Pressure in processing container: 1 to 100 mTorr (0.13 to 13.3 Pa)
Flow rate of Ru₃(CO)₁₂ gas: 1 to 5 sccm
Flow rate of CO gas: 300 to 700 sccm

### Experimental Example

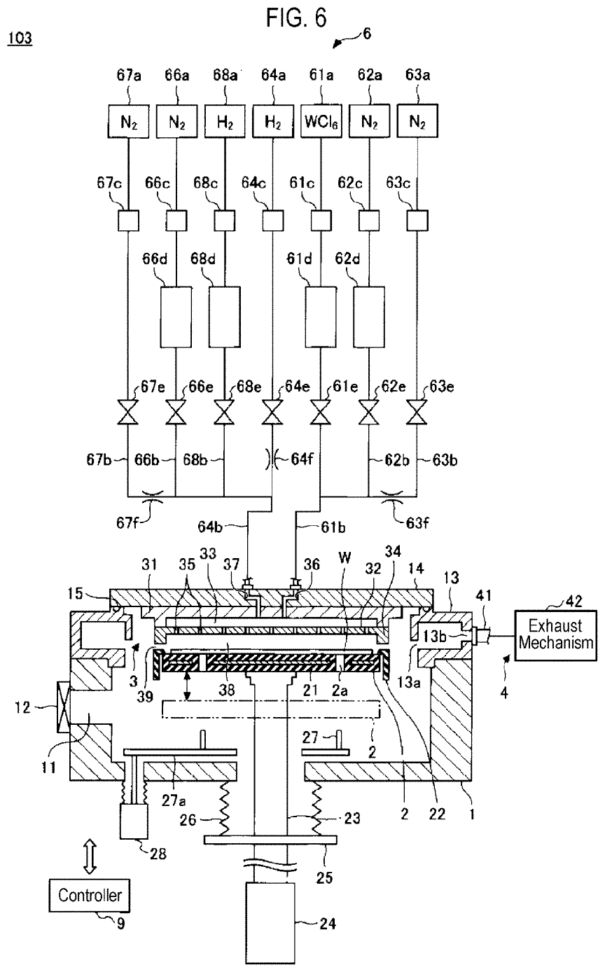

Next, an experimental example will be described. FIG. 7 is an explanatory view of an experimental procedure of a selective growth of a ruthenium film.

In the experimental example, as illustrated in FIG. 7, a ruthenium (Ru) film having a thickness of 20 nm was formed through a thermal CVD method on a sample in which a TiN film 1002 and a line-patterned SiO₂ film 1003 were stacked on a substrate 1001. The section of the produced sample was observed using a scanning electron microscope (SEM).

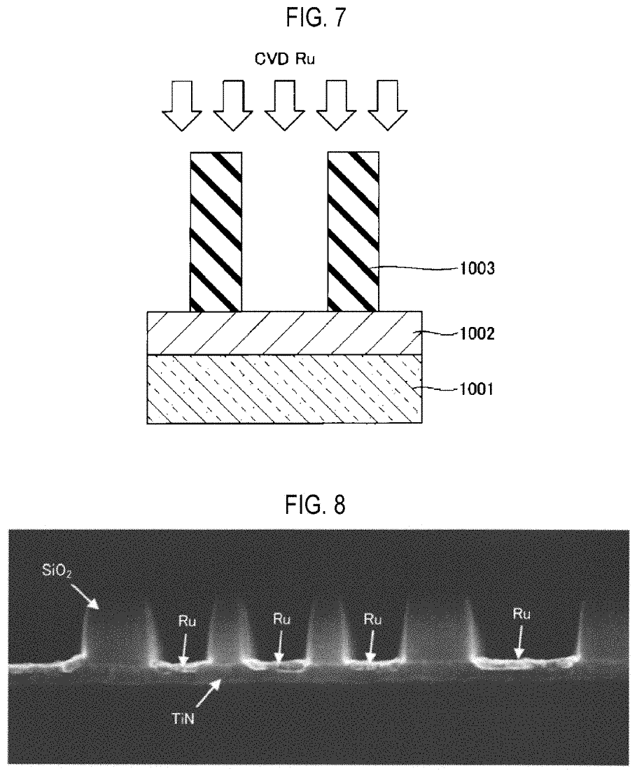

FIG. 8 is an SEM photograph showing a state in which a ruthenium film is selectively grown on a TiN film present on a bottom portion of a recess. As shown in FIG. 8, it was observed that the ruthenium film was formed on a surface of the TiN film, whereas no ruthenium film was formed on a surface of the SiO₂ film. From this, it was confirmed that a ruthenium film can be grown in a bottom-up fashion by remaining the TiN film on the bottom portion in the recess.

In the above embodiment, a semiconductor wafer has been described as an example of a substrate, but the semiconductor wafer may be a silicon wafer, or a compound semiconductor wafer of GaAs, SiC, GaN, or the like. Furthermore, the substrate is not limited to the semiconductor wafer, and may be a glass substrate used for a flat panel display (FPD) such as a liquid crystal display device, a ceramic substrate, or the like.

In the above embodiment, a single wafer processing apparatus that processes wafers sheet by sheet has been described as an example, but the present disclosure is not limited thereto. For example, a batch type apparatus that processes a plurality of wafers at a time may be used.

According to the present disclosure, it is possible to suppress pattern collapse when a metal film is embedded in a recess.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A film forming method of embedding a metal film in a recess, which is formed in a substrate and has an insulating film formed on a surface of the recess, the method comprising:
conformally forming a base film in the recess;
etching the base film such that a surface of the insulating film formed on an upper portion of an inner wall of the recess is exposed and the base film remains on a bottom portion in the recess; and
selectively growing the metal film on the base film remaining on the bottom portion in the recess.

2. The film forming method of claim 1, wherein the etching the base film is performed in a supply rate limiting state.

3. The film forming method of claim 1, wherein the selectively growing the metal film is performed by supplying a gas having an incubation time shorter for the base film than for the insulating film.

4. The film forming method of claim 1, wherein the conformally forming the base film, the etching the base film, and the selectively glowing the metal film are consecutively performed in the same processing container.

5. The film forming method of claim 1, wherein the conformally forming the base film, the etching the base film, and the selectively glowing the metal film are performed in separate processing containers, which are connected to one another via a vacuum transfer chamber.

6. The film forming method of claim 1, wherein the conformally forming the base film is performed through an atomic layer deposition (ALD) method using a titanium-containing gas.

7. The film forming method of claim 1, wherein the etching the base film is performed through an etching process using a halogen-containing gas.

8. The film forming method of claim 1, wherein the selectively growing the metal film is performed through a chemical vapor deposition (CVD) method or an atomic layer deposition (ALD) method using a tungsten-containing gas or a ruthenium-containing gas.

9. A substrate processing system for embedding a metal film in a recess, which is formed in a substrate and has an insulating film formed on a surface of the recess, the system comprising:
a vacuum transfer chamber in which a transfer mechanism configured to transfer the substrate in a depressurized state is provided;
a first processing apparatus, a second processing apparatus, and a third processing apparatus, which are connected to one another via the vacuum transfer chamber; and
a controller,
wherein the controller is configured to control the vacuum transfer chamber, the first processing apparatus, the second processing apparatus, and the third processing apparatus so as to execute the following processes in order of recitation:
transferring the substrate to the first processing apparatus by the transfer mechanism, and conformally forming a base film in the recess in the first processing apparatus;
transferring the substrate from the first processing apparatus to the second processing apparatus by the transfer mechanism via the vacuum transfer chamber, and etching the base film such that a surface of the insulating film formed on an upper portion of an inner wall of the recess is exposed and the base film remains on a bottom portion in the recess; and
transferring the substrate from the second processing apparatus to the third processing apparatus by the transfer mechanism via the vacuum transfer chamber, and selectively growing the metal film on the base film remaining on the bottom portion in the recess.

10. A substrate processing system for embedding a metal film in a recess, which is formed in a substrate and has an insulating film formed on a surface of the recess, the system comprising:
a processing apparatus; and
a controller,
wherein the controller is configured to transfer the substrate to the processing apparatus, and to control the processing apparatus to execute the following processes in order of recitation:
conformally forming a base film in the recess;
etching the base film such that a surface of the insulating film formed on an upper portion of an inner wall of the recess is exposed and the base film remains on a bottom portion in the recess; and
selectively growing the metal film on the base film remaining on the bottom portion in the recess.
